(19) United States
(12) Patent Application Publication
(10) Pub. No.: US 2013/0001710 A1
(43) Pub. Date: Jan. 3, 2013

(54) PROCESS FOR A SEALED MEMS DEVICE WITH A PORTION EXPOSED TO THE ENVIRONMENT

(75) Inventors: Michael J. DANEMAN, Campbell, CA (US); Martin LIM, San Mateo, CA (US); Joseph SEEGER, Menlo Park, CA (US); Igor TCHERTKOV, San Jose, CA (US); Steven S. NASIRI, Saratoga, CA (US)

(73) Assignee: INVENSENSE, INC., Sunnyvale, CA (US)

(21) Appl. No.: 13/536,896

(22) Filed: Jun. 28, 2012

Related U.S. Application Data
(60) Provisional application No. 61/502,603, filed on Jun. 29, 2011.

(51) Int. Cl. H01L 21/50; H01L 29/84

(52) U.S. Cl. 257/415; 438/51; 438/50; 257/E21.499; 257/E29.324

(57) ABSTRACT

A method and system for providing a MEMS device with a portion exposed to an outside environment are disclosed. The method comprises bonding a handle wafer to a device wafer to form a MEMS substrate with a dielectric layer disposed between the handle and device wafers. The method includes lithographically defining at least one standoff on the device wafer and bonding the at least one standoff to an integrated circuit substrate to form a sealed cavity between the MEMS substrate and the integrated circuit substrate. The method includes defining at least one opening in the handle wafer, standoff, or integrated circuit substrate to expose a portion of the to expose a portion of the device wafer to the outside environment.

### CROSS-REFERENCE TO RELATED APPLICATION

This application claims the benefit of U.S. Provisional Patent Application No. 61/502,603, filed on Jun. 29, 2011, entitled “MEMS DEVICE, FABRICATION PROCESS, INTEGRATED SENSORS, PRESSURE SENSORS, OPTICAL SENSORS, MICRO-FLUIDIC, ACCELEROMETER,” which is incorporated herein by reference in its entirety. This application is related to U.S. Provisional Patent Application No. 61/502,616 filed Jun. 29, 2011, docket # IVS-156PR (5028PR), titled “HERMITICALLY SEALED MEMS DEVICE WITH A PORTION EXPOSED TO THE ENVIRONMENT AND WITH VERTICALLY INTERGRATED ELECTRONIC,” and U.S. patent application Ser. No. ______ docket # IVS-156 (5028P), entitled “HERMETICALLY SEALED MEMS DEVICE WITH A PORTION EXPOSED TO THE ENVIRONMENT WITH VERTICALLY INTEGRATED ELECTRONICS,” filed concurrently herewith and assigned to the assignee of the present invention, all of which are incorporated herein in their entireties.

### FIELD OF THE INVENTION

The present invention relates to Microelectromechanical Systems (MEMS) devices, and more particularly, to fabrication of MEMS devices with portions exposed to the outside environment.

### BACKGROUND

Many MEMS devices, specifically those measuring or modifying aspects of the environment outside of the device (e.g. pressure sensors, microphones, speakers, chemical sensors, biological sensors, optical sensors etc.) require a portion of the MEMS structure exposed to the outside environment. There is a strong need for a cost-effective and efficient fabrication process that implements and improves operation of such MEMS devices by fabricating devices with portions exposed to the outside environment. The present invention addresses such a need.

### SUMMARY OF THE INVENTION

A method and system for providing a MEMS device with a portion exposed to an outside environment are disclosed. In a first aspect, the method comprises bonding a handle wafer to a device wafer to form a MEMS substrate with a dielectric layer disposed between the handle and device wafers. The method includes lithographically defining at least one standoff on the device wafer and bonding the at least one standoff to an integrated circuit substrate to form a sealed cavity between the MEMS substrate and the integrated circuit substrate. The method includes etching at least one opening in the handle wafer to expose a portion of the dielectric layer and etching the exposed portion of the dielectric layer to expose a portion of the device wafer to the outside environment.

In a second aspect, the MEMS device comprises a CMOS substrate and a MEMS substrate bonded to the CMOS substrate. The MEMS substrate includes a handle substrate bonded to a device substrate with a dielectric layer disposed between the handle and device substrates. The MEMS device includes at least one opening in the handle substrate, wherein the at least one opening exposes a surface of the device substrate to the outside environment.

### BRIEF DESCRIPTION OF THE DRAWINGS

The accompanying figures illustrate several embodiments of the invention and, together with the description, serve to explain the principles of the invention. One of ordinary skill in the art readily recognizes that the particular embodiments illustrated in the figures are merely exemplary, and are not intended to limit the scope of the present invention.

FIG. 1 illustrates a starting material for a first MEMS device in accordance with an embodiment.

FIG. 2 illustrates the first MEMS device with a first etch of the handle wafer in accordance with an embodiment.

FIG. 3 illustrates the first MEMS device with a second etch of the dielectric layer in accordance with an embodiment.

FIG. 4a illustrates the first MEMS device with an optional third etch of the device wafer in accordance with an embodiment.

FIG. 4b illustrates the first MEMS device where the etched opening is located over a stand-off frame, such that the dimensions of a flexible portion of the device wafer are defined by the location of the stand-off frame rather than the location and dimensions of the etched opening.

FIG. 5 illustrates a MEMS device with a device wafer that comprises two layers of silicon in accordance with an embodiment.

FIG. 6 illustrates a first wafer-level packaging process of the first MEMS device in accordance with an embodiment.

FIG. 7 illustrates a second wafer-level packaging process of the first MEMS device in accordance with an embodiment.

FIG. 8 illustrates the photoresist patterning deposition of the second wafer-level packaging process in accordance with an embodiment.

FIG. 9 illustrates a plastic-molding packaging process of a MEMS device in accordance with an embodiment.

FIG. 10a illustrates a MEMS device in accordance with an embodiment.

FIG. 10b illustrates a second MEMS device in accordance with an embodiment.

FIG. 11 illustrates a top view of a cavity of a MEMS device in accordance with an embodiment.

FIG. 12 illustrates a cross-section view A-A′ of the MEMS device of FIG. 11 in accordance with an embodiment.

FIG. 13 illustrates a cross-section view of a MEMS device with a cavity exposed to the outside environment through a standoff layer side-channel in accordance with an embodiment.

FIG. 14 illustrates a top view and a cross-section view of a MEMS device with a side-channel defined by a cavity in the CMOS wafer in accordance with an embodiment.

FIG. 15 illustrates a MEMS device in accordance with an embodiment.

FIG. 16 illustrates a fabrication process of a MEMS device to create a CMOS wafer opening in accordance with an embodiment.

FIG. 17 illustrates a MEMS device in accordance with an embodiment.

FIG. 18 illustrates a fabrication process of thinning a portion of a device wafer prior to fusion bonding to a handle wafer of a MEMS device in accordance with an embodiment.

FIG. 19 illustrates a further fabrication process of a MEMS device that has been thinned and processed according to the fabrication process of FIG. 18 in accordance with an embodiment.

### DETAILED DESCRIPTION

The present invention relates to Microelectromechanical Systems (MEMS) devices, and more particularly, to fabrication of MEMS devices with portions exposed to the outside environment. The following description is presented to enable one of ordinary skill in the art to make and use the invention and is provided in the context of a patent application and its requirements. Various modifications to the described embodiments and the generic principles and features described herein will be readily apparent to those skilled in the art. Thus, the present invention is not intended to be limited to the embodiments shown but is to be accorded the widest scope consistent with the principles and features described herein.

A CMOS-MEMS integrated process can be utilized to create hermetically sealed MEMS devices that are integrated with CMOS wafers/substrates through wafer bonding. The resulting MEMS devices are sealed inside the resulting enclosure and do not have direct exposure to the environment. For some devices including but not limited to pressure sensors, optical MEMS, biological sensors, it is desirable for the MEMS structure to directly interface with the environment.

A method and system in accordance with the present invention provides a process for fabricating a MEMS device with a portion exposed to an outside environment. By bonding a MEMS substrate to an integrated circuit substrate and etching a portion of the MEMS substrate, the portion of the MEMS substrate is then exposed to the outside environment. The portion of the MEMS substrate that is exposed to the outside environment may be thinner than the remaining structural device layers of the MEMS substrate to enable the creation of a pressure sensor or related MEMS device that requires enhanced sensitivity. The integration of such pressure sensor or related MEMS devices with other MEMS devices including but not limited to motion sensors is also achieved by the fabrication process.

To describe the features of the present invention in more detail, refer now to the following description in conjunction with the accompanying Figures.

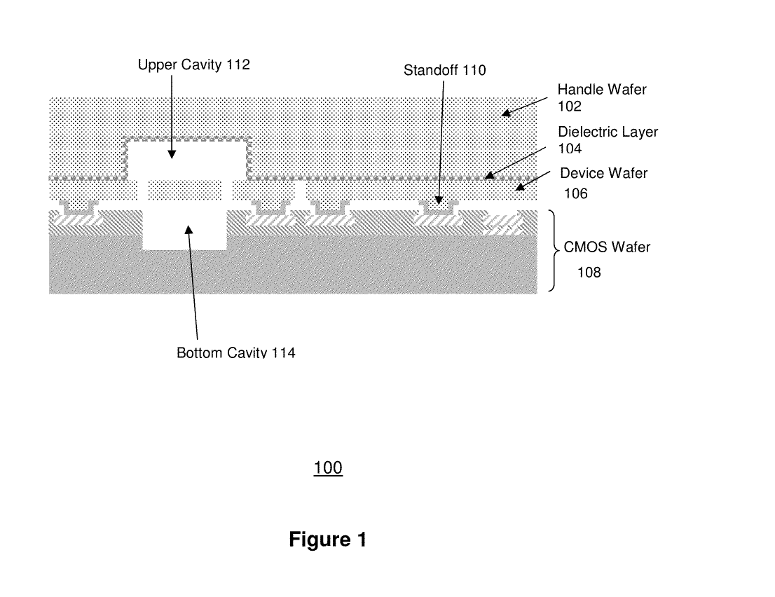

FIG. 1 illustrates a starting material for a MEMS device 100 in accordance with an embodiment. The MEMS device 100 includes a MEMS substrate that comprises a handle wafer 102 and a device wafer 106 coupled to the handle wafer 102 via a dielectric layer 104. In one embodiment, the device wafer 106 is a pure silicon wafer. In one embodiment, the dielectric layer 104 is an oxide layer. The MEMS device 100 includes a CMOS wafer 108 coupled to the device wafer 106 of the MEMS substrate via at least one standoff 110. The MEMS device 100 includes an upper cavity 112 and a bottom cavity 114.

Thus, MEMS device 100 is a starting CMOS-MEMS bonded wafer that is created through a standard process. A top surface of the MEMS substrate is coated by a photoresist material and an opening is photolithographically defined over a region of the MEMS substrate that is to be exposed to the outside environment. In one embodiment, the starting wafer has a portion of the MEMS structural device layer thinned to a desired thickness prior to bonding with the CMOS wafer.

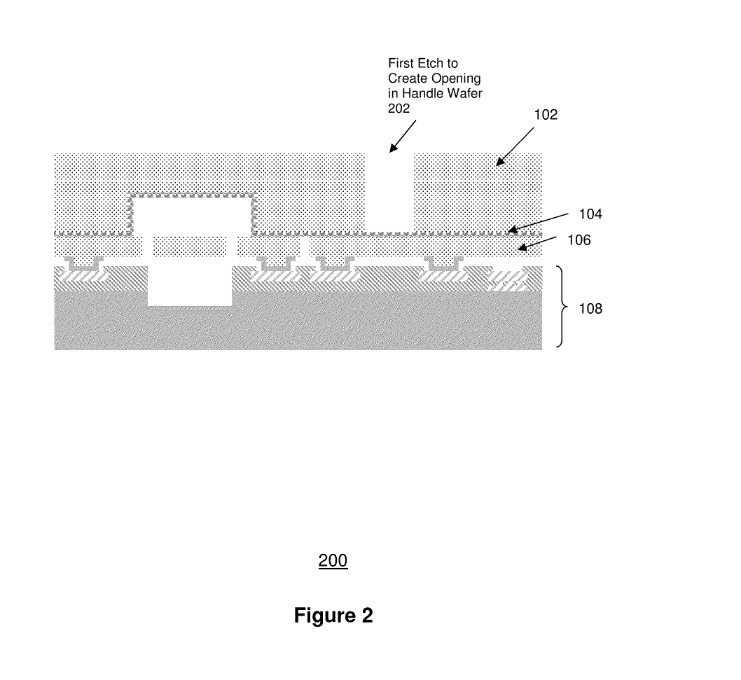

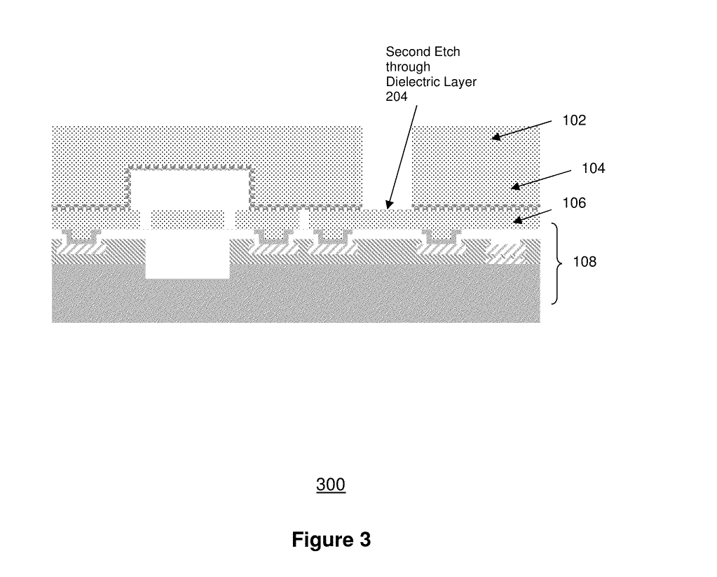

FIG. 2 illustrates the MEMS device 200 with a first etch 202 of the handle wafer 102 in accordance with an embodiment. In one embodiment, the first etch 202 is a membrane DRIE etch through the handle wafer 102 that stops when it reaches a top surface of the dielectric layer 104 that is buried below the handle wafer 102, which creates an initial opening or cavity in the handle wafer 102. FIG. 3 illustrates the MEMS device 300 with a second etch 204 of the handle wafer 102 in accordance with an embodiment. In one embodiment, the second etch 204 is a membrane DRIE etch through the dielectric layer 104 that stops when it reaches a top surface of the device wafer 106. At this point, the top surface of the device wafer 106 is now exposed to the outside environment.

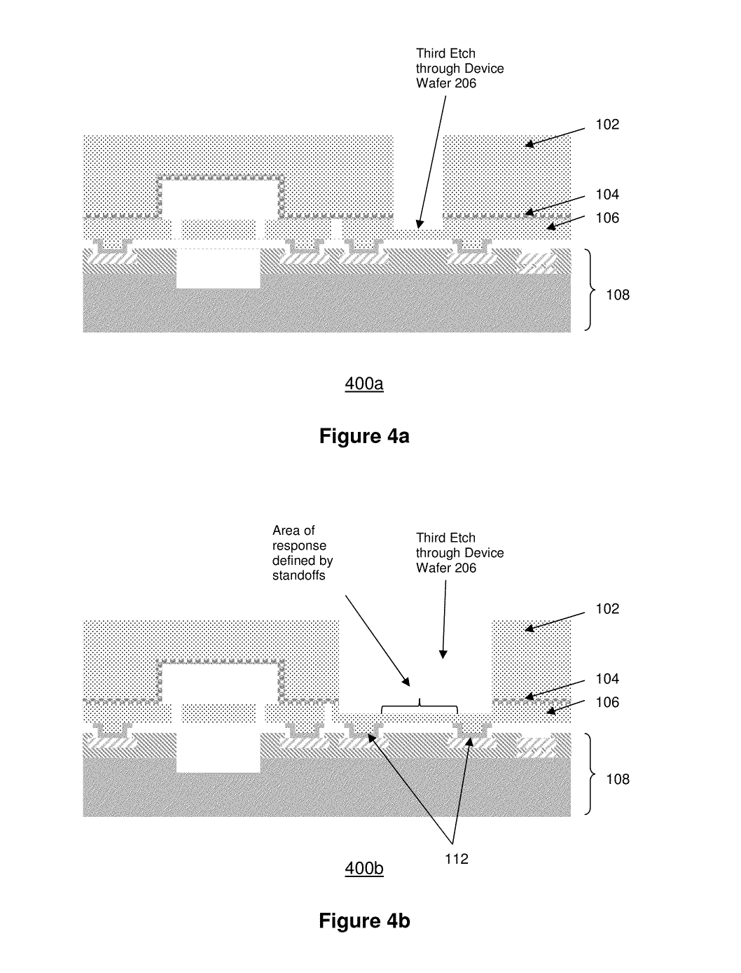

FIG. 4a illustrates the MEMS device 400a with an optional third etch 206 of the handle wafer 102 in accordance with an embodiment. In one embodiment, the third etch 206 is a membrane DRIE etch through the device wafer 106 that stops when it reaches a desired membrane thickness. One of ordinary skill in the art readily recognizes that the desired membrane thickness can vary in accordance with differing needs and applications and that would be within the spirit and scope of the present invention. Each of the first, second, and third etches 202-206 can be timed so as to stop the etch process at predetermined time periods and exacting thickness levels. Additionally, each of the first, second, and third etches 202-206 are selectively etched using a wet or dry etch.

FIG. 4b is an embodiment where the lateral membrane dimensions are determined by a contiguous standoff frame, 112. The diameter of the membrane, 116, is determined by the inner dimensions of the standoff frame. This membrane size definition may have superior lateral dimensional control than membranes defined by the first, second, and, third etches patterned from the topside of handle wafer, 102

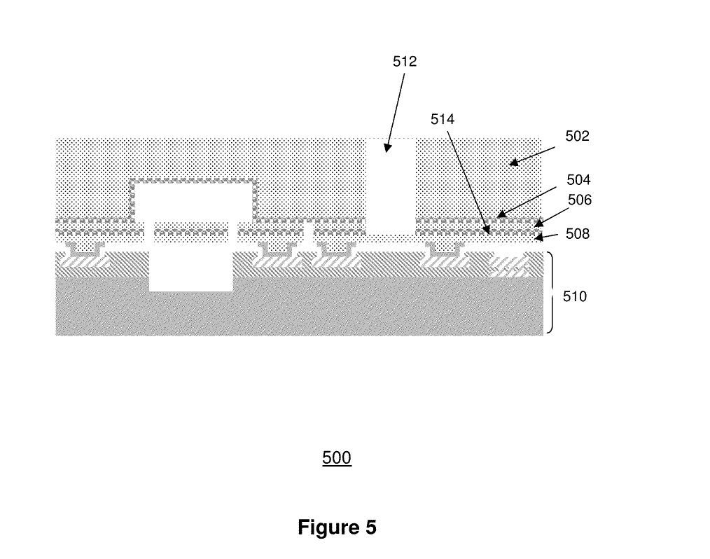

In one embodiment, the device wafer 106 comprises two layers of silicon, a top structural layer and a bottom structural layer, fusion bonded through a dielectric. FIG. 5 illustrates a MEMS device 500 with a device wafer that comprises two layers of silicon in accordance with an embodiment. The MEMS device 500 includes a MEMS substrate that comprises a handle wafer 502, a top structural layer 506 of a device wafer bonded to the handle wafer 502 via a first dielectric layer 504, and a bottom structural layer 508 of the device wafer bonded to the top structural layer 506 of the device wafer via a second dielectric layer 514. The MEMS device 500 includes a CMOS wafer 510 coupled to the bottom structural layer 508 of the device wafer.

In FIG. 5, an opening 512 is produced from the etching of handle wafer 502, dielectric layer 504, top structural layer 506, and second dielectric layer 514. This reveals bottom structural layer, 508 Thus, a thickness of the remaining structural layer is defined by a thickness of the bottom structural layer 508 of the device wafer and not by an etch duration.

In one embodiment, an additional substrate with fluidic or gas channels is bonded to a top surface of the MEMS substrate to create a fluidic or gas interface to an exposed portion of the MEMS device. One of ordinary skill in the art readily recognizes that the additional substrate can be bonded to a variety of surfaces including but not limited to a top surface of the handle wafer of the MEMS substrate and that would be within the spirit and scope of the present invention. In another embodiment, the opening in the handle wafer and oxide layers is created by non-etching means including but not limited to saw dicing, laser drilling, laser-assisted etching, and mechanical drilling.

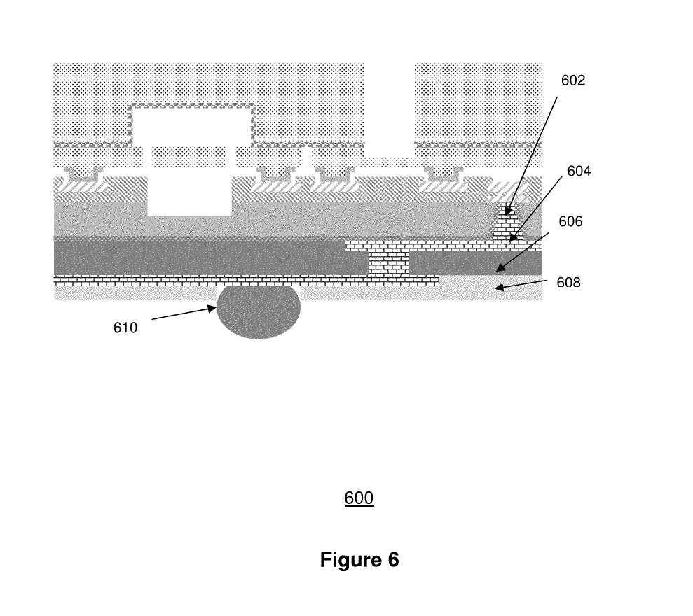

FIG. 6 illustrates a wafer-level packaging process 600 of the MEMS device 100 in accordance with an embodiment. The MEMS device 100 has undergone the process described by FIGS. 2-4. The wafer-level packaging process 600 includes a Through-Silicon-Via (TSV) 602 that makes contact with the CMOS wafer metal, a redistribution metallization 604, a stress-relief and electrical isolation layer 606, a solder mask 608, and a solder ball 610. In another embodiment, a wedge dicing technique in combination with insulating and conducting makes contact with the CMOS wafer metal.

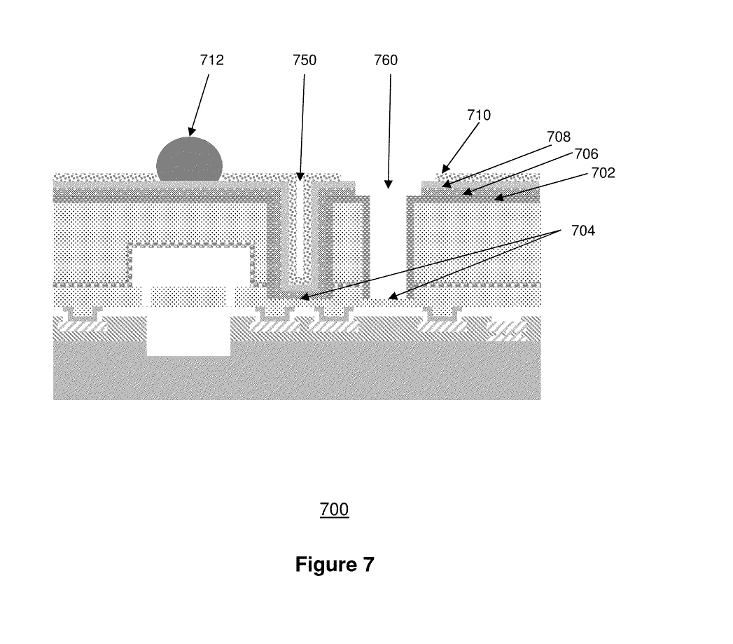

In one embodiment, the wafer-level packaging process is done using TSV from the MEMS substrate side which allows the process that etches the handle wafer to simultaneously create a port to expose the structural layer and define a via for the TSV contacts required for the wafer-level packaging process. In this embodiment, great care must be taken to protect the MEMS membrane layers from metallization and solder mask deposition. FIG. 7 illustrates a wafer-level packaging process 700 of the MEMS device 100 in accordance with an embodiment. The MEMS device 100 has undergone the MEMS substrate side etch process described by FIGS. 2-4 and additionally, another timed membrane DRIE etch process that results in two openings 750 and 760 in the handle wafer 102.

The wafer-level packaging process 700 includes depositing a Silicon Dioxide (SiO2) insulator layer 702 using chemical vapor deposition (CVD) or a sputter method. The SiO2 insulator layer 702 is deposited over the entire top surface of the handle wafer 102 of the MEMS device 100 including each surface within the two openings that were previously etched. Only the bottom surfaces 704 of the two openings 750 and 760 that included the deposited SiO2 layer are etched. A first photoresist patterning is deposited in the opening 760 and then a redistribution layer (RDL) 706 is deposited using a lift-off process. An electroplating top metal 708 is deposited on top of the RDL 706. In one embodiment, the electroplating top metal 708 is Copper (Cu).

A second photoresist patterning is deposited in both the opening 760 and on a top surface on a left side of the handle wafer 702 and then an insulating solder mask layer 710 is deposited using a lift-off process. Finally, a solder ball 712 is deposited into the insulating solder mask layer 710 using screen/stencil printing. One of ordinary skill in the art readily recognizes that the solder ball 712 can be deposited by a variety of methodologies and that would be within the spirit and scope of the present invention.

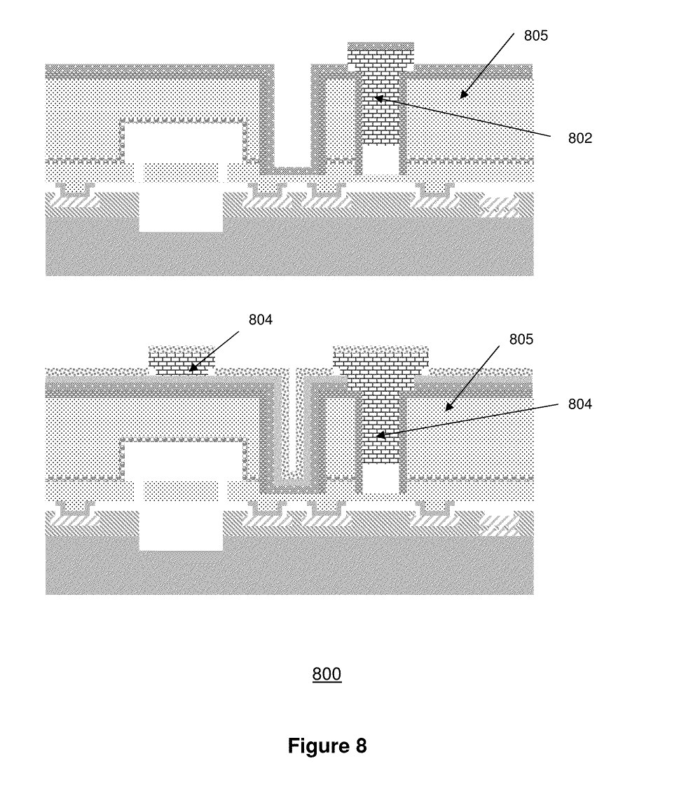

FIG. 8 illustrates the photoresist patterning deposition 800 of FIG. 7 in accordance with an embodiment. The photoresist patterning deposition 800 includes a first photoresist patterning 802 deposited in the opening 760 and a second photoresist patterning 804 deposited in both the opening 760 and the top surface on the left side of the handle wafer 805.

A MEMS device can also be packaged in a plastic-molded package with a handle wafer that is combined with a mold cap that acts like a dam to prevent a mold compound from entering an opening/cavity in the handle wafer and contacting an exposed device layer. In one embodiment, the mold cap uses a soft material including but not limited to tape which enhances sealing of the opening/cavity in the handle wafer.

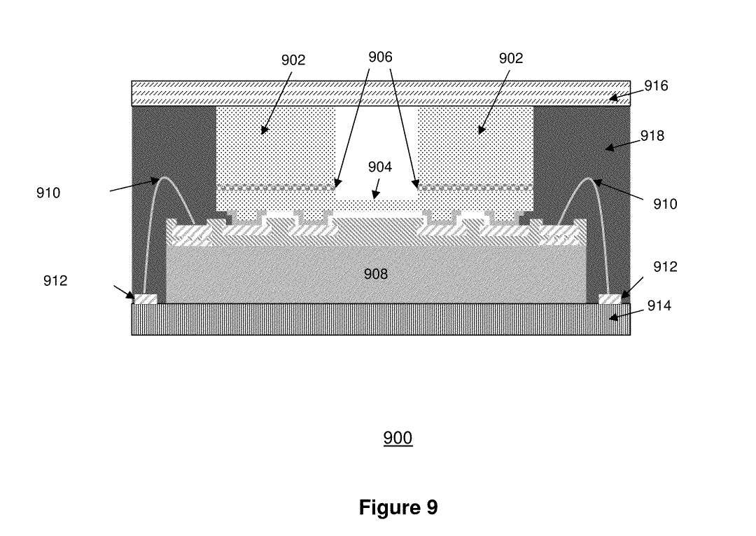

FIG. 9 illustrates a plastic-molding packaging process 900 of a MEMS device in accordance with an embodiment. The MEMS device includes a MEMS substrate comprising a handle wafer 902 and a device wafer 904 coupled to the handle wafer 902 via a dielectric layer 906. The MEMS substrate is bonded to a CMOS wafer 908. The CMOS wafer 908 is coupled to package pads 912 of a package lead frame 914 via wire bonding 910.

The plastic-molding packaging process 900 includes singulating die of the MEMS device and attaching the die to the package lead frame 914 via the wire bonding 910. The plastic-molding packaging process 900 includes coupling a mold cap 916 to a top surface of the handle wafer 902 of the MEMS device. Once a molding compound 918 is applied to the MEMS device, the mold cap 916 prevents the molding compound 918 from entering an opening of the handle wafer 902 and coming in contact with exposed device layers of the MEMS device. After the molding compound 918 application has completed, the mold cap 916 is removed and the MEMS device is singulated.

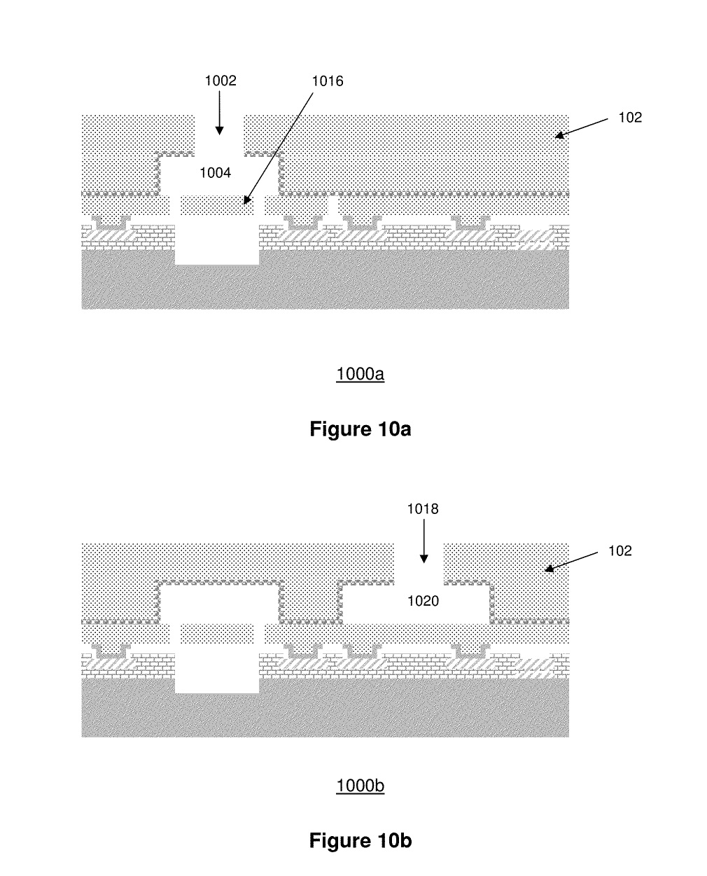

In one embodiment, the etch process of the MEMS device is done on an area of the handle wafer that is located above the exposed device layers. FIG. 10a illustrates a MEMS device 1000 in accordance with an embodiment. The MEMS device 1000a includes a MEMS substrate bonded to a CMOS substrate via at least one standoff. The handle wafer of the MEMS device 1000a has been etched in a region 1002 located above an upper cavity 1004 of the MEMS device 1000 that is exposed to the outside environment. There are three distinct benefits for an upper cavity, 1004. First, the termination of the etched region to the upper cavity allows a free structure 1016 to be exposed. This structure may be but is not limited to a torsional mirror or other light modulating structure. A second benefit shown in FIG. 10b is the reduction of the etching depth of the handle wafer 102. The etched region 1018 is thinner than the full thickness of the handle wafer 102 which results in a faster cycle time and lower manufacturing cost. The third benefit of the upper cavity 1020 is that its lateral dimension is better controlled and its alignment to the membrane defined by the standoffs 110 more accurate than those of the etched region 1018. Both alignment and etch profile of upper cavity 1020 are superior to those of the etched region 1020 which is performed after CMOS-MEMS bonding. The improvement in the overlay of the upper cavity 1018 with respect to the standoffs 110 is expected to reduce any degradation of package sensitivity due to misalignment or imbalance.

In one embodiment, a section of a device wafer of the MEMS device is exposed to the outside environment by extending an upper cavity of the MEMS device to a dicing lane edge so that the upper cavity is exposed to the outside environment when the MEMS device is singulated, thus creating a side-channel exposed to the outside environment. One of ordinary skill in the art readily recognizes that this embodiment can be utilized in a variety of applications including but not limited to exposing a pressure-sensor flexible plate to outside environment pressure and that would be within the spirit and scope of the present invention.

In this embodiment, a cavity seal of the MEMS device is maintained during all pre-singulation wafer processing preventing the need to protect the openings in the handle wafer/MEMS device from process liquids, gasses, and residues. In another embodiment, the side-channel remains sealed by a variety of mechanisms including but not limited to a narrow side plate and a fusion bond after singulation to protect the side-channel from singulation residues. The narrow side plate or fusion bond is then opened at a later stage through a puncturing process including but not limited to laser machining and laser dicing.

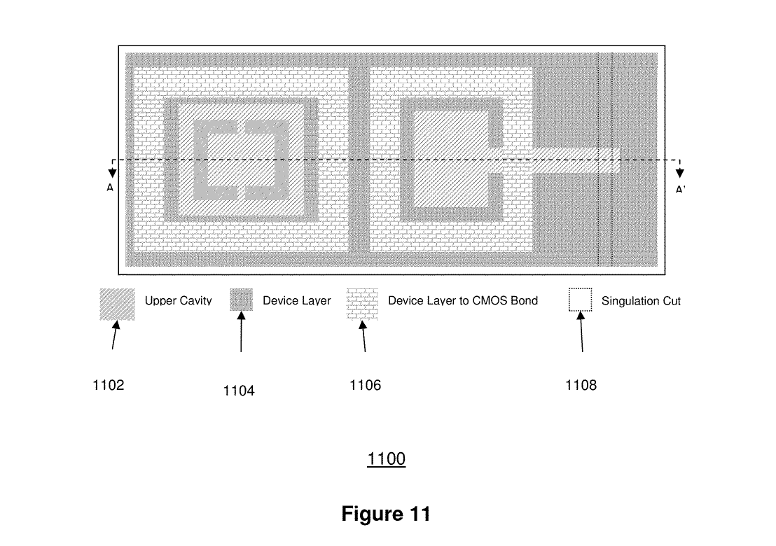

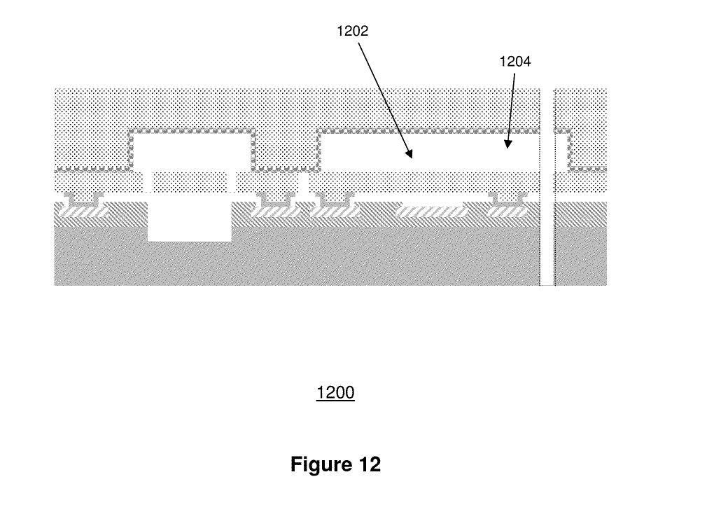

FIG. 11 illustrates a top view 1100 of a cavity of a MEMS device in accordance with an embodiment. The cavity of the MEMS device is exposed to an outside environment. The MEMS device 1100 includes an upper cavity 1102, a device layer 1104, a bond 1106 between the device layer 1104 and a CMOS wafer, and a singulation cut 1108. FIG. 12 illustrates a cross-section view A-A′ 1200 of the MEMS device of FIG. 11 in accordance with an embodiment. The MEMS device 1200 includes an upper cavity 1202 that has been extended to a dicing lane edge and a side-channel 1204 that is connected to a portion of the device wafer that is exposed to the outside environment.

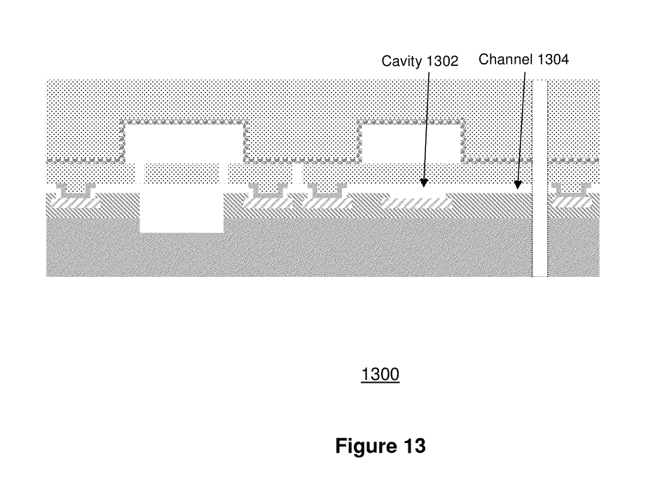

FIG. 13 illustrates a cross-section view A-A′ 1300 of a MEMS device with a cavity 1302 exposed to the outside environment through a standoff layer side-channel 1304 in accordance with an embodiment. The standoff layer side-channel is sealed off by a eutectic bond during fabrication, but the standoff layer side-channel is opened to the outside environment during die singulation. One of ordinary skill in the art readily recognizes that singulation can be accomplished in a variety of ways including but not limited to using a dicing saw or a dry process such as stealth dicing and laser dicing to avoid residue and that would be within the spirit and scope of the present invention.

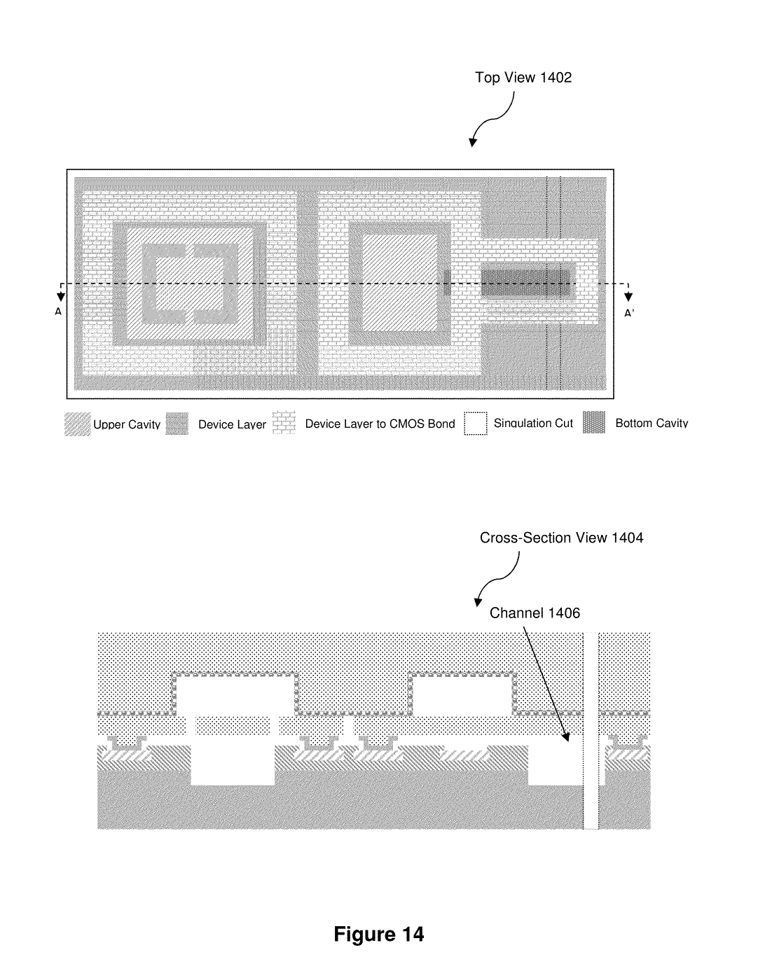

FIG. 14 illustrates a top view 1402 and a cross-section view 1404 of a MEMS device with a side-channel 1406 in accordance with an embodiment. In this embodiment, a cavity of a MEMS device exposed to the outside environment through a side-channel is achieved using a bottom cavity in the CMOS wafer. The side-channel is sealed off by a eutectic bond during fabrication, but the side-channel is opened to the outside environment during die singulation.

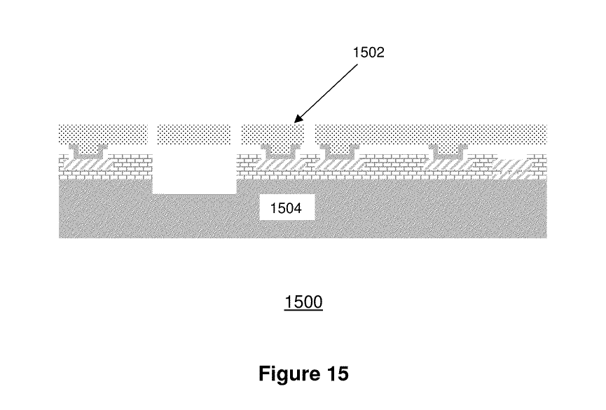

FIG. 15 illustrates a MEMS device 1500 in accordance with an embodiment. In this embodiment, the handle wafer of the MEMS device 1500 is completely removed by etching or grinding or a combination of both. The MEMS device 1500 includes a MEMS wafer 1502 and a base wafer 1504 coupled to the MEMS wafer 1502. The MEMS wafer 1502 does not include a handle wafer portion.

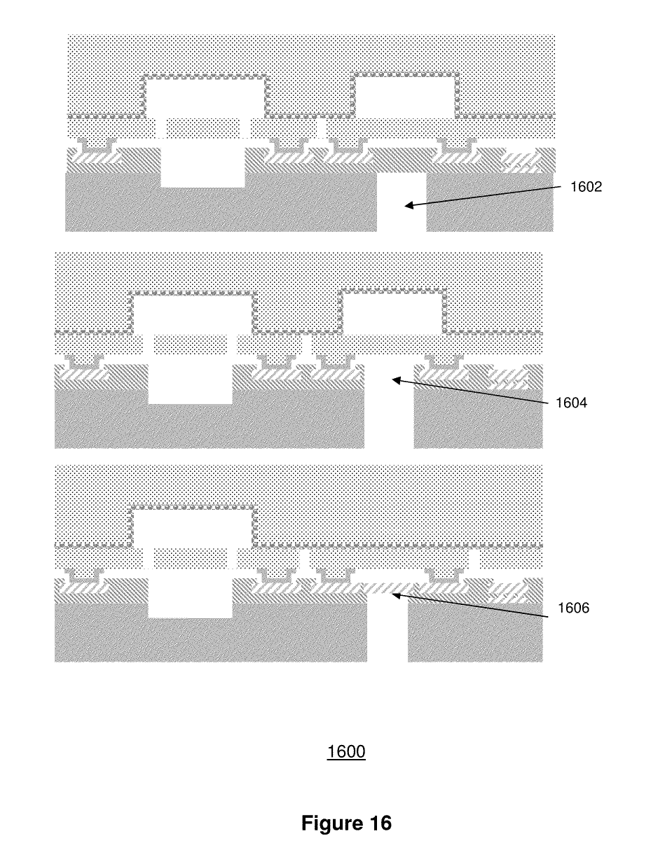

FIG. 16 illustrates a fabrication process 1600 of a MEMS device to create a CMOS wafer opening in accordance with an embodiment. The fabrication process 1600 includes etching (using wet or dry chemical etching) an opening in a CMOS wafer substrate silicon of the MEMS device, via step 1602. The fabrication process 1600 then either includes etching entirely through CMOS inter-metal dielectric and passivation layers to expose a MEMS portion of the MEMS device to the outside environment, via step 1604, or includes partially exposing a metal membrane compound of one or more CMOS metals and dielectric layers, via step 1606. The etching produces a through hole in the CMOS thereby exposing a MEMS feature. In step 1606, the MEMS device layer is used as a stationary electrode to capacitively sense motion of the metal membrane.

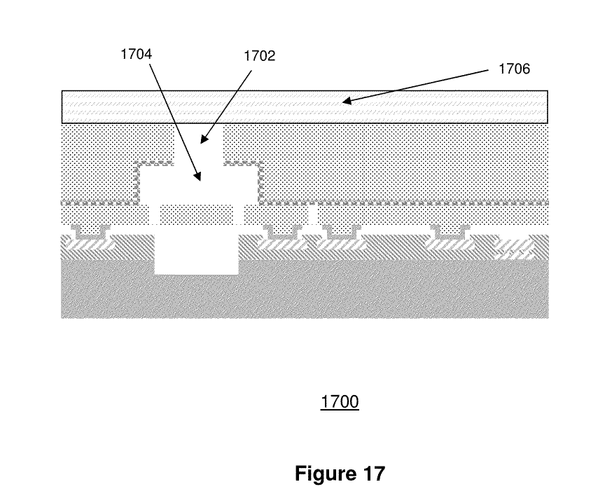

FIG. 17 illustrates a MEMS device 1700 in accordance with an embodiment. The MEMS device 1700 resembles the MEMS device 1000 of FIG. 10. Thus, the MEMS device 1700 includes an opening 1702 etched over and connected to an upper cavity 1704 of the MEMS device 1700. In FIG. 17, a transparent plate 1706 is bonded to a top surface of a MEMS substrate portion of the MEMS device 1700 to allow a coupling and interaction with optical signals. In one embodiment, the transparent plate 1706 is a wafer that is transparent to certain wavelengths of light. The transparent plate 1706 also protects the MEMS substrate portion from environmental gases, moisture, and particles.

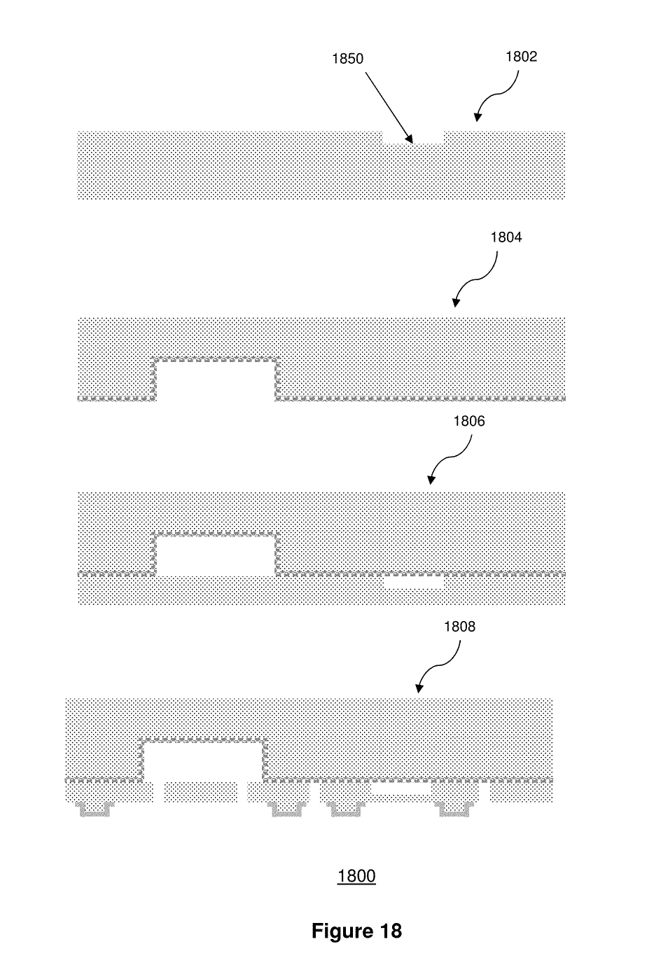

The device layer or substrate of the aforementioned MEMS devices is thinned during the aforementioned fabrication processes. In one embodiment, a portion of the device wafer to be exposed to the outside environment is thinned prior to fusion bonding to the handle wafer. FIG. 18 illustrates a fabrication process 1800 of thinning a portion of a device wafer prior to fusion bonding to a handle wafer of a MEMS device in accordance with an embodiment. The fabrication process 1800 includes forming a recess 1850 in a portion of the device wafer to produce a reduced thickness region via step 1802 and forming a cavity in the handle wafer via step 1804. An oxide is deposited onto the cavity side of the handle wafer and the handle wafer is fusion bonded to the device wafer such that the recess of the device wafer is facing towards the handle wafer, via step 1806. In step 1806, a device layer of a MEMS device comprising a device wafer fusion bonded to a handle wafer is thinned by grinding and polishing of the device wafer to a desired thickness.

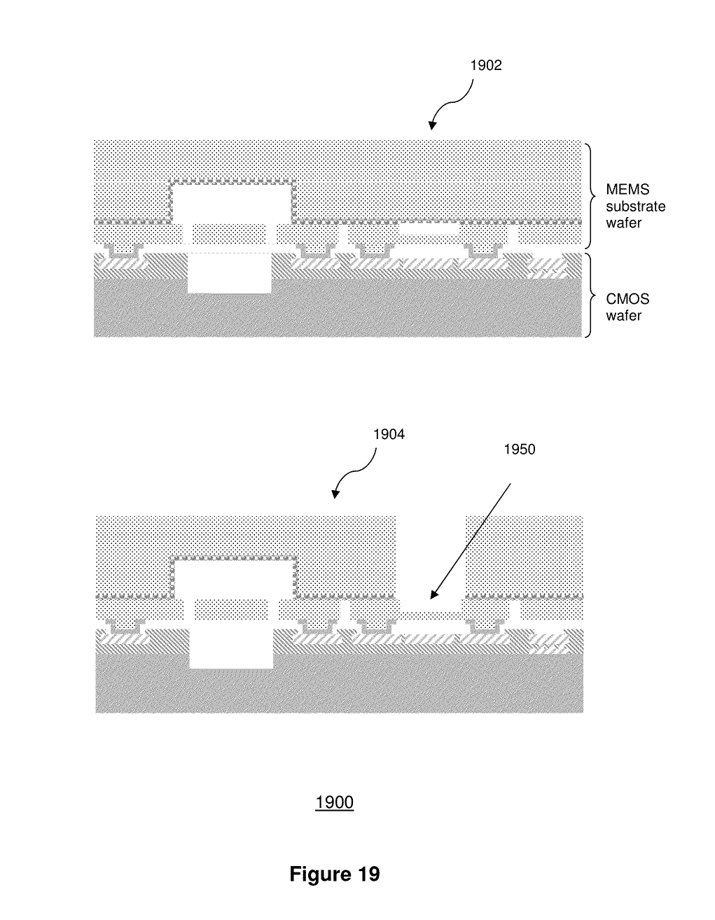

The fabrication process 1800 includes further processing and thinning of the device layer/MEMS substrate wafer by forming a plurality of standoffs on the device wafer, depositing Germanium or another material, and patterning and etching the device layer, via step 1808. FIG. 19 illustrates a fabrication process 1900 of a MEMS device that has been processed according to the fabrication process 1800 in accordance with an embodiment. The resulting MEMS substrate wafer is bonded to a CMOS wafer, via step 1902 and then the recessed portion of the device layer 1950 is exposed to the outside environment by utilizing any of the aforementioned techniques, via step 1904.

In one embodiment, port openings in the aforementioned MEMS devices that are exposed to the outside environment are fully or partially filled with a porous material including but not limited to Gortex to allow gasses or liquids to still penetrate to the MEMS portion while protecting the MEMS device from larger particles and objects.

As above described, the method and system allow for the fabrication of more efficient and more accurate force sensing and force exerting MEMS devices. By coupling an integrated circuit substrate to a MEMS substrate and utilizing an open handle wafer cavity, a top surface of the MEMS substrate structural layer is exposed to the outside environment. On one side of a flexible plate of the MEMS substrate is a hermetically sealed cavity/chamber while the other side is exposed to the surrounding ambient environment.

The approach disclosed in accordance with an embodiment allows wafer-level integration of environment-exposed MEMS structures with CMOS wafers and also allows the integration of such structures with other non-exposed structures on a same die that has varying levels of thickness. Specifically, the structural layer thickness of the exposed device on the die may be different (e.g. thinner) than that of the structural layer thickness of the other devices on the die. This enables the exposed device to benefit from increased sensitivities. Additionally, the method and system provide wafer-level packaging of these MEMS devices without damaging or compromising the exposed structural layer.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for providing a Microelectromechanical Systems (MEMS) device with a portion exposed to an outside environment, the method comprising:
bonding a handle wafer to a device wafer to form a MEMS substrate, wherein a dielectric layer is disposed between the handle and device wafers;
lithographically defining at least one standoff on the device wafer;
bonding the at least one standoff to an integrated circuit substrate to form a sealed cavity between the MEMS substrate and the integrated circuit substrate;
etching at least one opening in the handle wafer to expose a portion of the dielectric layer; and
etching the exposed portion of the dielectric layer to expose a portion of the device wafer to the outside environment.

2. The method of claim 1, wherein the integrated circuit substrate comprises a CMOS wafer with at least one electrode and at least one circuit coupled to the at least one electrode.

3. The method of claim 1, wherein a gap of the sealed cavity is defined by a height of the at least one standoff.

4. The method of claim 1, further comprising:
creating an electrical connection between the device wafer and the integrated circuit substrate by utilizing a conductive bond between the at least one standoff and the integrated circuit substrate.

5. The method of claim 1, wherein the exposed portion of the device wafer is a flexible plate, wherein at least one region of the flexible plate is a surface of the sealed cavity.

6. The method of claim 1, further comprising:
partially etching the exposed portion of the device wafer to reduce thickness of the device wafer.

7. The method of claim 1, further comprising:
completely etching the exposed portion of the device wafer to expose a surface of the integrated circuit substrate.

8. The method of claim 1, further comprising:
bonding a substrate with fluidic channels to a top surface of the MEMS substrate.

9. The method of claim 1, further comprising:
packaging the MEMS device using a Through-Silicon-Via process.

10. The method of claim 1, further comprising:
packaging the MEMS device in a plastic molded package using the handle wafer as a dam to prevent a molding compound from entering a membrane area of the sealed cavity.

11. The method of claim 1, further comprising:
packaging the MEMS device in a plastic molded package using adhesion tape to prevent a molding compound from entering a membrane area of the sealed cavity.

12. The method of claim 1, wherein etching the at least one opening in the handle wafer further produces sloped sidewalls.

13. A method for providing a Microelectromechanical Systems (MEMS) device with a portion exposed to an outside environment, the method comprising:
bonding a handle wafer to a device wafer to form a MEMS substrate, wherein a dielectric layer is disposed between the handle and device wafers;
lithographically defining at least one standoff on the device wafer;
providing a channel extending to an edge of a device;
bonding the at least one standoff to an integrated circuit substrate to form a sealed cavity between the MEMS substrate and the integrated circuit substrate;
singulating the MEMS device by cut through a portion of at least one channel thereby exposing the at least one channel to the outside environment.

14. The method of claim 13 wherein the provided channel is defined by etching one or more cavities in the handle wafer.

15. The method of claim 13 wherein the provided channel is defined by one or more gaps in the at least one standoff.

16. The method of claim 13 wherein the provide channel is created by etching one or more cavities in the integrated circuit substrate.

17. A Microelectromechanical Systems (MEMS) device with a portion exposed to an outside environment comprising:
a CMOS substrate;
a MEMS substrate bonded to the CMOS substrate, wherein the MEMS substrate includes a handle substrate bonded to a device substrate with a dielectric layer disposed between the handle and device substrates; and
at least one opening in the handle substrate, wherein the at least one opening exposes a surface of the device substrate to the outside environment.

18. The MEMS device of claim 17, wherein a section of the at least one opening extends to an edge of the handle substrate.

19. The MEMS device of claim 18, wherein the at least one opening is a fluidic channel that allows fluid flow.

20. The MEMS device of claim 17, wherein a sealed cavity is formed between the MEMS substrate and the CMOS substrate and is defined by a height of at least one standoff lithographically defined on the device substrate.

21. The MEMS device of claim 20 wherein the sealed cavity is smaller than the opening in the handle wafer located over the frame

22. The MEMS device of claim 20 wherein the sealed cavity is larger than the opening in the handle wafer located over the frame

23. The MEMS device of claim 20, wherein the at least one opening is located over the sealed cavity.

24. The MEMS device of claim 17, wherein the device substrate further comprises:
a top structural layer bonded to a bottom structural layer with a second dielectric layer disposed between the top and bottom structural layers, wherein the top structural layer is disposed between the dielectric layer and the second dielectric layer.

25. The MEMS device of claim 24, wherein the at least one opening extends through the dielectric layer and the top structural layer to expose a region of the second dielectric layer to the outside environment.

26. The MEMS device of claim 17, comprising at least one cavity in the handle substrate wherein the at least one opening in the handle substrate extends into the at least one cavity in the handle substrate.

27. The MEMS device of claim 17, wherein the at least one opening extends to the edge of the device.
